(19) United States
(12) Patent Application Publication
(10) Pub. No.: US 2010/0052165 A1
(43) Pub. Date: Mar. 4, 2010

(54) SEMICONDUCTOR DEVICE INCLUDING COLUMNAR ELECTRODES HAVING PLANAR SIZE GREATER THAN THAT OF CONNECTION PAD PORTION OF WIRING LINE, AND MANUFACTURING METHOD THEREOF

(75) Inventor: Norihiko KANEKO, Fussa-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 12/509,534

(22) Filed: Jul. 27, 2009

(30) Foreign Application Priority Data
Sep. 1, 2008 (JP) 2008-223028

(51) Int. Cl. H01L 23/498; H01L 21/768

(52) U.S. Cl. 257/738; 438/613; 257/E23.069; 257/E21.589

(57) ABSTRACT

A plurality of wiring lines are provided on a first protective film, a second protective film having an opening in a part corresponding to a connection pad portion of a wring line is provided on the first protective film including the wiring line, a columnar electrode is provided on the upper surface of the connection pad portion of the wring line exposed via the opening in the second protective film and on the second protective film around the connection pad portion.

### CROSS-REFERENCE TO RELATED APPLICATIONS

This application is based upon and claims the benefit of priority from prior Japanese Patent Application No. 2008-223028, filed Sep. 1, 2008, the entire contents of which are incorporated herein by reference.

### BACKGROUND OF THE INVENTION

1. Field of the Invention

This invention relates to a semiconductor device and a manufacturing method thereof.

2. Description of the Related Art

Jpn. Pat. Appln. KOKAI Publication No. 2008-84919 discloses what is called a chip size package (CSP), for example, as shown in FIG. 13. This chip size package includes an insulating film 33 and a protective film 34 provided on a semiconductor substrate 31 having a plurality of connection pads 32 on its upper surface; a wiring line 35 provided on the upper surface of the protective film 34 so that this wiring line is connected to the connection pads 32; a columnar electrode 36 provided on the upper surface of a connection pad portion of the wiring line 35; a sealing film 37 provided on the upper surface of the protective film 34 including the wiring line 35 so that the upper surface of this sealing film is flush with the upper surface of the columnar electrode 36; and a solder ball 38 provided on the upper surface of the columnar electrode 36. In this case, the wiring line 35 includes a connection portion 35a connected to the connection pad 32, a connection pad portion 35b at the end, and a drawn line 35c between the connection portion and the connection pad portion.

Now, according to Jpn. Pat. Appln. KOKAI Publication No. 2008-84919, in general, the plurality of columnar electrodes 36, that is, the plurality of connection pad portions 35b of the wiring lines 35 serving as seats of the columnar electrodes 36 are arranged in a matrix form. Further, the drawn line 35c of the wiring line 35 having the connection pad portion which serves as a seat of the columnar electrode 36 located on the center of the semiconductor substrate 31 is disposed between the adjacent connection pad portions 35b of the wiring line 35 located on the peripheral parts on the semiconductor substrate 31.

One example of the dimensions of a semiconductor device having such a configuration is described here. The pitch of the columnar electrodes 36 is 500 μm when both the line width of the drawn line 35c of the wiring line 35 and the distance between the wiring lines 35 are 20 μm at the minimum. In this case, if the diameter of the columnar electrode 36 is 250 μm, the diameter of the connection pad portion 35b of the wiring line 35 serving as the seat of the columnar electrode 36 is 270 μm because a tolerance of 10 μm on a single side amounts to 20 μm on both sides, the distance between the adjacent connection pad portions 35b of the wiring line 35 is 230 μm, and the number of the drawn lines 35c of the wiring lines 35 that can be arranged between the adjacent connection pad portions 35b of the wiring line 35 is five.

As described above, in Jpn. Pat. Appln. KOKAI Publication No. 2008-84919, given that the diameter of the columnar electrode 36 is 250 μm when the pitch of the columnar electrodes 36 is 500 μm, the diameter of the connection pad portion 35b of the wiring line 35 serving as the seat of the columnar electrode 36 is 270 μm and relatively great, the distance between the adjacent connection pad portions 35b of the wiring line 35 is 230 μm and relatively small, and the number of the drawn lines 35c of the wiring line 35 that can be arranged between the adjacent connection pad portions 35b of the wiring line 35 is five and relatively small. This disadvantageously imposes limitations on the drawing of the wiring line 35.

It is therefore an object of this invention to provide a semiconductor device and a manufacturing method thereof which permit a wider distance between connection pad portions of a wiring line and which permits less limitations on the drawing of the wiring line.

### BRIEF SUMMARY OF THE INVENTION

A plurality of wiring lines are provided on a first protective film. A second protective film having an opening in a part corresponding to a connection pad portion of a wring line 7 is provided on the first protective film including the wiring line. A columnar electrode is provided on the upper surface of the connection pad portion of the wring line exposed via the opening in the second protective film and on the second protective film around the connection pad portion. Thus, the planar size of the connection pad portion of the wring line is smaller than the planar size of the columnar electrode, and the distance between the connection pad portions of the wring line can be greater, such that the drawing of the wiring line can be less limited.

According to a first aspect of the present invention, there is provided a semiconductor device including a semiconductor substrate having integrated circuits formed in one surface; a plurality of connection pads respectively connected to the integrated circuits along at least one combination of opposite sides of the semiconductor substrate; a first insulating film provided above the semiconductor substrate; a plurality of first wiring lines which are provided on the first insulating film and which are arranged so that connection pad portions thereof form an outer circle; second wiring lines which extend between the connection pad portions of the first wiring lines and which are arranged so that connection pad portions thereof form at least one circle inside the outer circle; a second insulating film which is provided on the first insulating film as well as on the first and second wiring lines and which has openings in parts corresponding to the connection pad portions of the first and second wiring lines; and columnar electrodes which are provided above the upper surfaces of the connection pad portions of the first and second wiring lines exposed via the openings in the second insulating film and above the second insulating film around these connection pad portions, the columnar electrodes having a planar size greater than the planar size of the connection pad portions of the first and second wiring lines.

According to a second aspect of the present invention, there is provided a semiconductor device manufacturing method comprising the steps of preparing a semiconductor substrate which has integrated circuits formed in one surface and which has a plurality of connection pads respectively connected to the integrated circuits along at least one combination of opposite sides of the semiconductor substrate; forming, above the semiconductor substrate, a first insulating film having openings, the openings exposing at least parts of the connection pads; forming a plurality of first wiring lines and a plurality of second wiring lines on the first insulating film formed on the semiconductor substrate, the plurality of first wiring lines respectively having connection pad portions, the plurality of second wiring lines respectively having connection pad portions; forming a second insulating film on the first insulating film as well as on the first and second wiring lines, the second insulating film having openings in parts corresponding to the connection pad portions of the first and second wiring lines; and forming columnar electrodes above the upper surfaces of the connection pad portions of the first and second wiring lines exposed via the openings in the second insulating film and above the second insulating film around these connection pad portions, the columnar electrodes having a planar size greater than the planar size of the connection pad portions of the first and second wiring lines, wherein the step of forming the wiring lines includes arranging the first wiring lines so that the connection pad portions thereof form an outer circle, and arranging the second wiring lines to extend between the connection pad portions of the first wiring lines so that the connection pad portions thereof form at least one circle inside the outer circle.

According to this invention, the first wiring lines are arranged on the first insulating film so that the connection pad portions of the first wiring lines form the outer circle. The second wiring lines are extended between the connection pad portions of the first wiring lines and arranged so that the connection pad portions thereof form at least one circle inside the outer circle. The second insulating film having openings in parts corresponding to the connection pad portions of the first and second wiring lines is provided on the first insulating film as well as on the first and second wiring lines. The columnar electrodes having a planar size greater than the planar size of the connection pad portions of the first and second wiring lines are provided on the upper surfaces of the connection pad portions of the first and second wiring lines exposed via the openings in the second insulating film and on the second insulating film around the connection pad portions. As a result, the planar size of the connection pad portions of the first wiring line arranged to form the outer circle is smaller than the planar size of the columnar electrode. This permits a greater distance between the connection pad portions of the first wiring line, and therefore permits less limitations on the drawing of the second wiring lines extending between the connection pad portions of the first wiring lines.

### BRIEF DESCRIPTION OF THE SEVERAL VIEWS OF THE DRAWINGS

FIG. 1 is a sectional view of a semiconductor device as one embodiment of this invention;

FIG. 2 is an actual transmitted plan view of the semiconductor device shown in FIG. 1 in which solder balls are omitted;

FIG. 3 is an enlarged transmitted plan view of a part indicated by a symbol A in FIG. 2;

FIG. 4 is a sectional view of initially prepared materials in one example of a method of manufacturing the semiconductor device shown in FIG. 1;

FIG. 5 is a sectional view in a step following FIG. 4;

FIG. 6 is a sectional view in a step following FIG. 5;

FIG. 7 is a sectional view in a step following FIG. 6;

FIG. 8 is a sectional view in a step following FIG. 7;

FIG. 9 is a sectional view in a step following FIG. 8;

FIG. 10 is a sectional view in a step following FIG. 9;

FIG. 11 is a sectional view in a step following FIG. 10;

FIG. 12 is a sectional view in a step following FIG. 11; and

FIG. 13 is a sectional view of one example of a conventional semiconductor device.

### DETAILED DESCRIPTION OF THE INVENTION

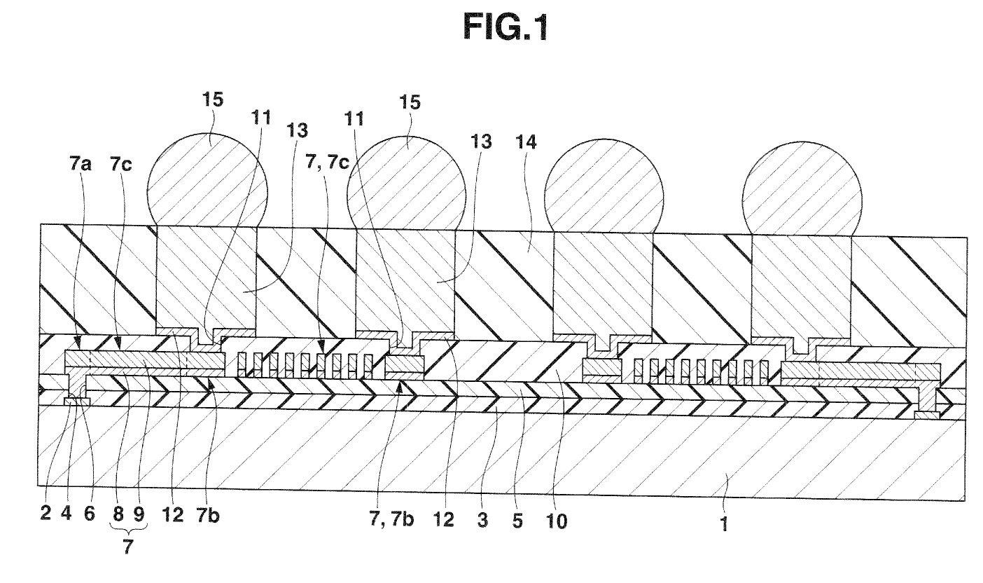

FIG. 1 shows a sectional view of a semiconductor device as one embodiment of this invention. This semiconductor device is generally called a CSP, and comprises a silicon substrate (semiconductor substrate) 1. Integrated circuits having predetermined functions, in particular, elements (not shown) such as transistors, diodes, resistors and condensers are formed on the upper surface of the silicon substrate 1. Connection pads 2 made of, for example, an aluminum-based metal and connected to the integrated circuits are provided in peripheral parts of the upper surface of the silicon substrate 1. Although two connection pads 2 are shown, a large number of connection pads 2 are actually arranged in the peripheral parts of the upper surface of the silicon substrate 1.

An insulating film 3 made of, for example, silicon oxide, is provided on the upper surface of the silicon substrate 1 except for the centers of the connection pads 2. The centers of the connection pads 2 are exposed via openings 4 provided in the insulating film 3. A first protective film (first insulating film) 5 made of, for example, a polyimide-based resin is provided on the upper surface of the insulating film 3. Openings 6 are provided in parts of the first protective film 5 corresponding to the openings 4 in the insulating film 3.

A wiring line 7 is provided on the upper surface of the first protective film 5. The wiring line 7 has a two-layer structure including a foundation metal layer 8 which is made of, for example, copper and which is provided on the upper surface of the first protective film 5, and an upper metal layer 9 which is made of copper and which is provided on the upper surface of the foundation metal layer 8. One end of the wiring line 7 is connected to the connection pad 2 via the openings 4 and 6 in the insulating film 3 and the first protective film 5. Here, the wiring line 7 includes a connection portion 7a connected to the connection pad 2, a connection pad portion 7b having a circular planar surface at the end, and a drawn line 7c between the connection portion and the connection pad portion.

A second protective film (second insulating film) 10 made of, for example, a polyimide-based resin is provided on the upper surface of the first protective film 5 including the wiring line 7. An opening 11 is provided in a part of the second protective film 10 corresponding to the circular connection pad portion 7b of the wiring line 7. A foundation metal layer 12 having a circular planar surface and made of, for example, copper is provided on the upper surface of the circular connection pad portion 7b of the wiring line 7 exposed via the opening 11 in the second protective film 10 and on the upper surface of the second protective film 10 around the circular connection pad portion 7b.

A columnar electrode 13 made of copper is provided on the upper surface of the foundation metal layer 12. In this case, the columnar electrode 13 is provided on the entire upper surface of the foundation metal layer 12 having a circular planar surface, and has a circular planar surface. The diameter (planar size) of the columnar electrode 13 is greater than the diameter (planar size) of the connection pad portion 7b of the wiring line 7. Thus, part of the drawn line 7c of the wiring line 7 can be located immediately under the columnar electrode 13.

A sealing film 14 made of, for example, an epoxy resin is provided on the upper surface of the second protective film 10 around the columnar electrode 13 including the foundation metal layer 12 so that the upper surface of this sealing film 14 may be flush with the upper surface of the columnar electrode 13. A solder bail 15 is provided on the upper surface of the columnar electrode 13.

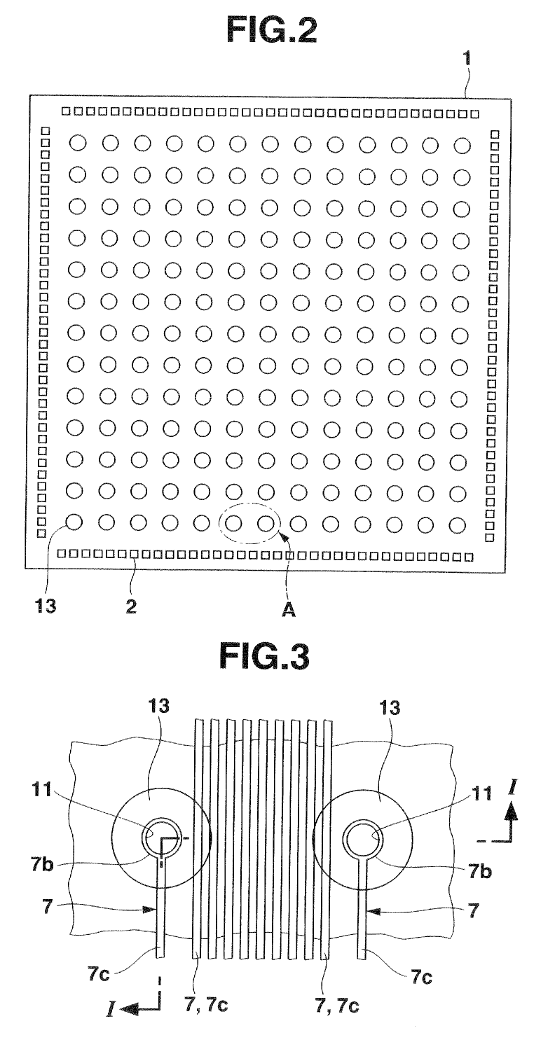

Although two connection pads 2 and four columnar electrodes 13 are only shown here in FIG. 1 as described above, there are actually a large number of connection pads 2 and a large number of columnar electrodes 13. By way of example, FIG. 2 shows an actual transmitted plan view of the semiconductor device shown in FIG. 1 in which the solder balls 15 are omitted.

As shown in FIG. 2, a large number of connection pads 2 are arranged along four sides or at least one combination of opposite sides of the silicon substrate 1, and a large number of columnar electrodes 13 are arranged on the silicon substrate 1 in a matrix form. Therefore, the connection pad portions 7b of the wiring line 7 provided immediately under the centers of the columnar electrodes 13 shown in FIG. 1 are arranged to form a plurality of circles.

FIG. 3 shows an enlarged transmitted plan view of a part indicated by a symbol A in FIG. 2. Here, the left side of FIG. 1 corresponds to the sectional view of a part along the line I-I in FIG. 3. The connection pad portions 7b of the wiring lines 7, hereinafter referred sometimes to as first wiring lines 7, provided immediately under the centers of the columnar electrodes 13 arranged on the outermost periphery in FIG. 2 are arranged to form an outermost circle.

The drawn lines 7c of the wiring lines 7 other than the first wiring lines 7 extend between the connection pad portions 7b of the first wiring lines 7, and the connection pad portions 7b of the second wiring lines 7 are arranged to form one circle or two or more circles inside the outermost circle. In addition, the second wiring lines 7 may be hereinafter referred to sometimes.

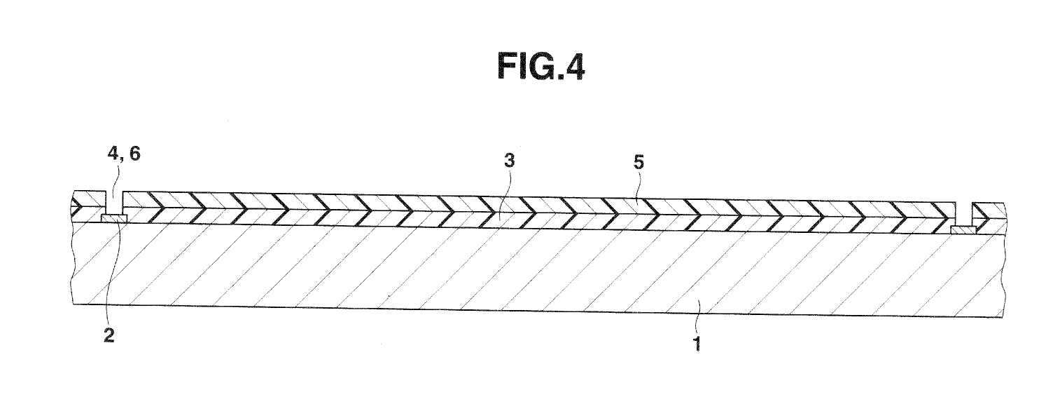

Now, one example of a method of manufacturing the semiconductor device having such a configuration is described. First, as shown in FIG. 4, the following materials are prepared on a silicon substrate 1 in a wafer state: a connection pad 2 made of, for example, an aluminum-based metal, an insulating film 3 made of, for example, silicon oxide, and a first protective film 5 made of, for example, a polyimide-based resin, wherein the center of the connection pad 2 is exposed via openings 4 and 6 formed in the insulating film 3 and the first protective film 5.

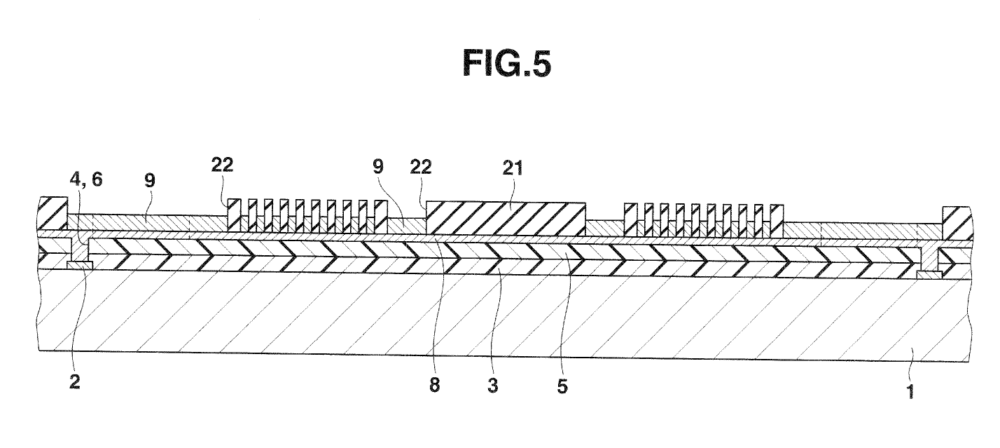

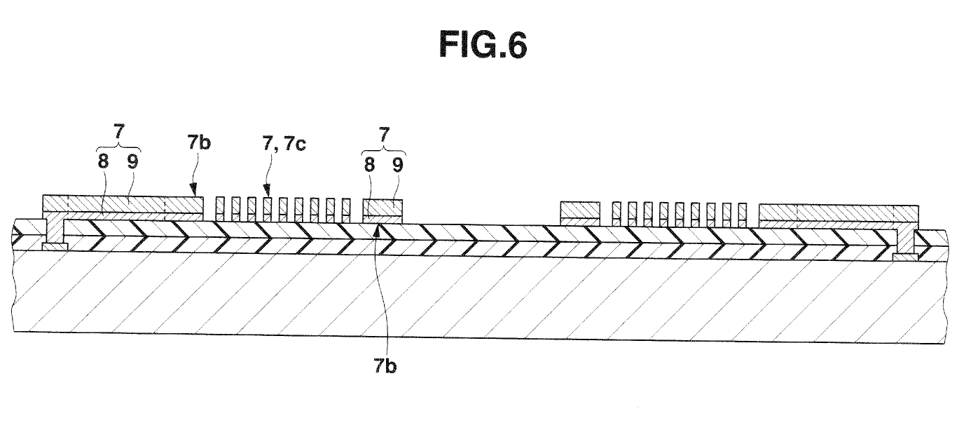

Then, as shown in FIG. 5, a foundation metal layer 8 is formed on the entire upper surface of the first protective film 5 including the upper surface of the connection pad 2 exposed via the openings 4 and 6 in insulating film 3 and the first protective film 5. In this case, the foundation metal layer 8 may only be a copper layer formed by electroless plating, may only be a copper layer formed by sputtering, or may be a copper layer formed by sputtering on a thin film layer such as titanium formed by sputtering.

Then, a plating resist film 21 is patterned/formed on the upper surface of the foundation metal layer 8. In this case, an opening 22 is formed in a part of the plating resist film 21 corresponding to a region where an upper metal layer 9 is to be formed. Further, electrolytic plating with copper is carried out using the foundation metal layer 8 as a plating current path, thereby forming the upper metal layer 9 on the upper surface of the foundation metal layer 8 within the opening 22 in the plating resist film 21.

Then, the plating resist film 21 is released, and then the foundation metal layer 8 in a region which is not under the upper metal layer 9 is etched and removed using the upper metal layer 9 as a mask, whereby the foundation metal layer 8 remains under the upper metal layer 9 alone, as shown in FIG. 16. In this state, a second wiring line 7 of a two-layer structure having a connection pad portion 7b is formed by the upper metal layer 9 and the foundation metal layer 8 remaining thereunder.

In this state, the connection pad portions 7b of the first wiring lines 7 are arranged to form the outermost circle. Drawn lines 7c of the second wiring lines 7 extend between the connection pad portions 7b of the first wiring lines 7, and the connection pad portions 7b of the second wiring lines 7 are arranged to form one circle or two or more circles inside the outermost circle.

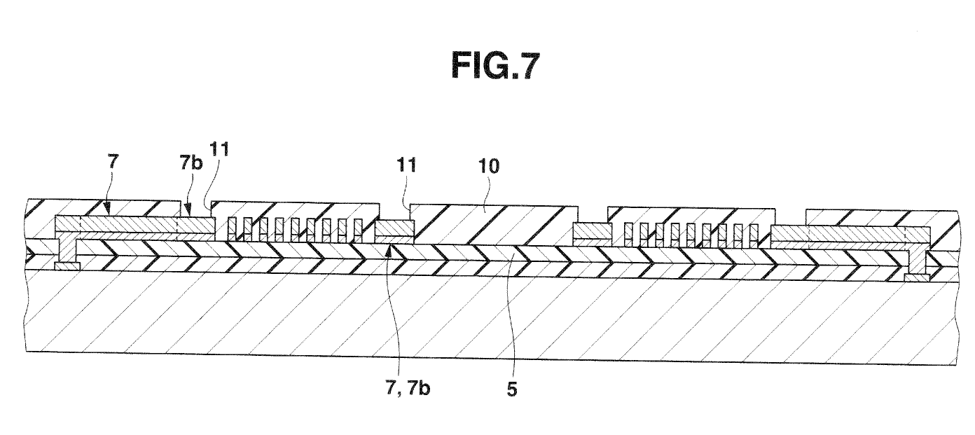

Then, as shown in FIG. 7, a second protective film.

10 made of, for example, a polyimide-based resin is formed on the upper surface of the first protective film 5 including the wiring line 7 by, for example, a screen printing method or a spin coat method. In this case, an opening 11 is formed by a photolithographic method in a part of the second protective film 10 corresponding to the connection pad portion 7b of the wiring line 7.

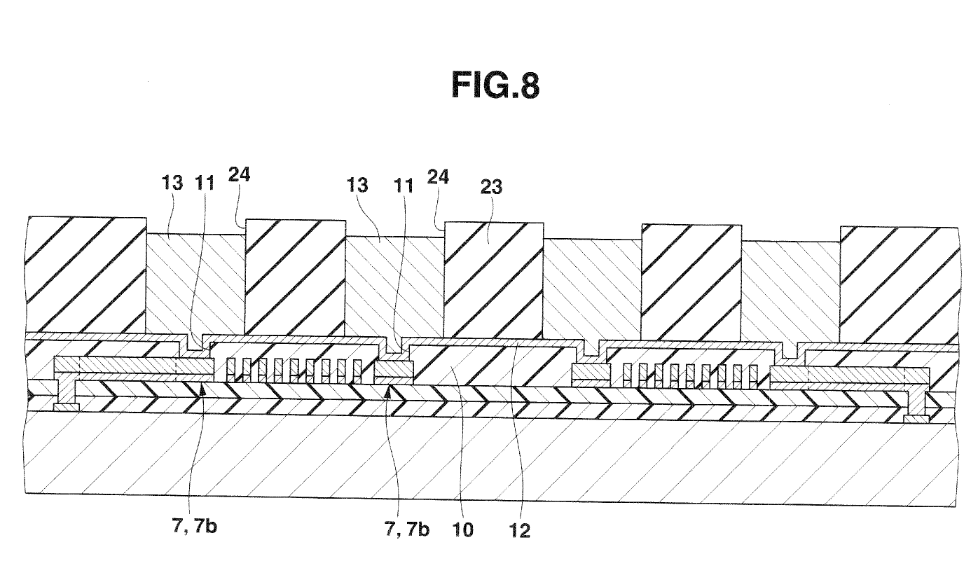

Then, as shown in FIG. 8, a plating resist film 23 is patterned/formed on the upper surface of the foundation metal layer 12 including the connection pad portion 7b of the wiring line 7 exposed via the opening 11 in the second protective film 10. In this case, a circular opening 24 is formed in a part of the plating resist film 23 corresponding to a region where a columnar electrode 13 is to be formed. Moreover, the diameter of the opening 24 in the plating resist film 23 is slightly greater than the diameter of the opening 11 in the second protective film 10.

Then, electrolytic plating with copper is carried out using the foundation metal layer 12 as a plating current path in order to form the columnar electrode 13 on the upper surface of the foundation metal layer 12 within the opening 24 in the plating resist film 23.

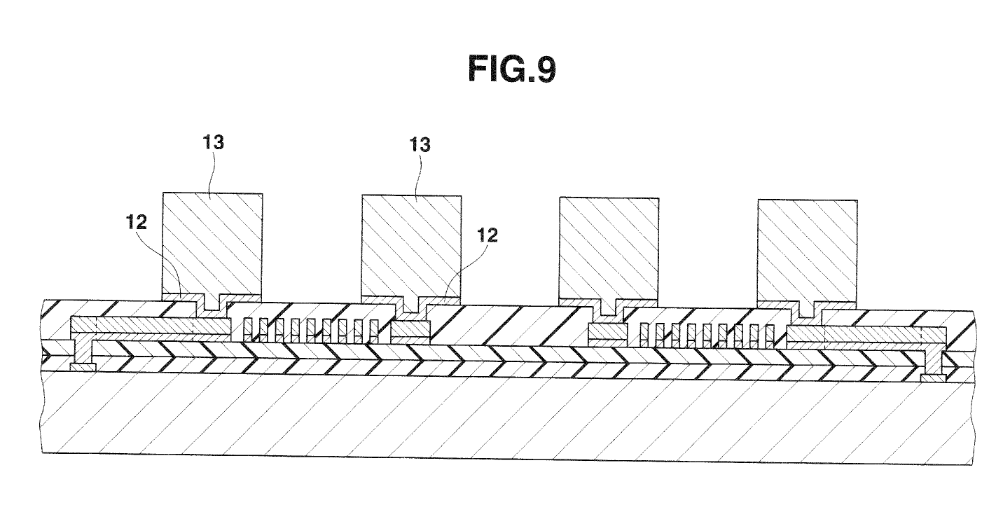

Then, the plating resist film 23 is released, and then the foundation metal layer 12 in regions which are not under the columnar electrodes 13 is etched and removed using the columnar electrodes 13 as masks, whereby the foundation metal layer 12 remains under the columnar electrodes 13 alone, as shown in FIG. 9.

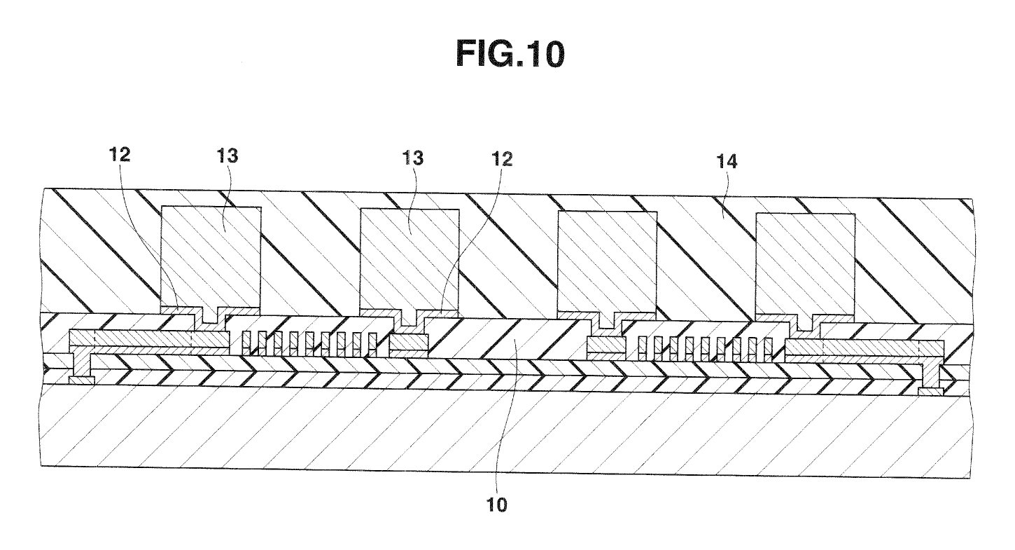

Then, as shown in FIG. 10, a sealing film 14 made of, for example, an epoxy resin is formed on the upper surface of the second protective film 10 including the foundation metal layer 12 and the columnar electrode 13 by, for example, the screen printing method or the spin coat method so that the thickness of this sealing film 14 may be greater than the height of the columnar electrode 13. Therefore, in this state, the upper surface of the columnar electrode 13 is covered with the sealing film 14.

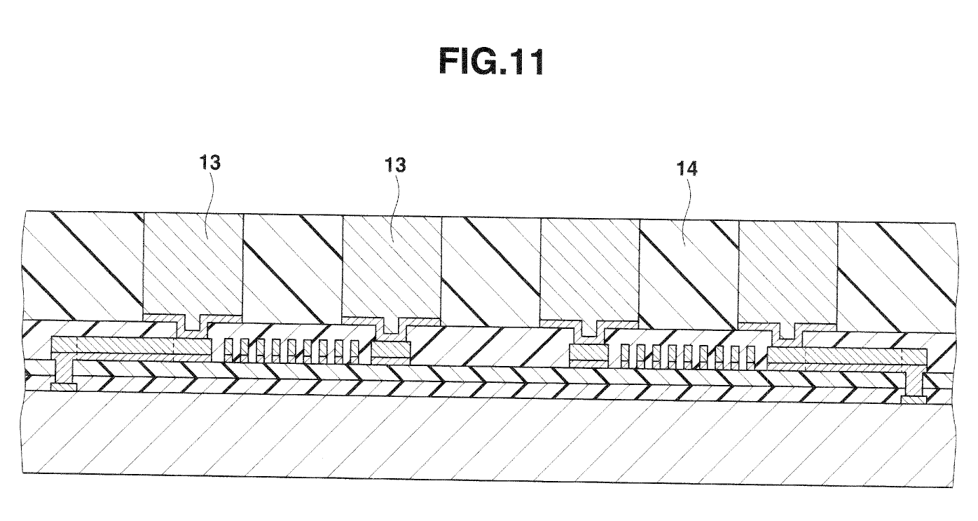

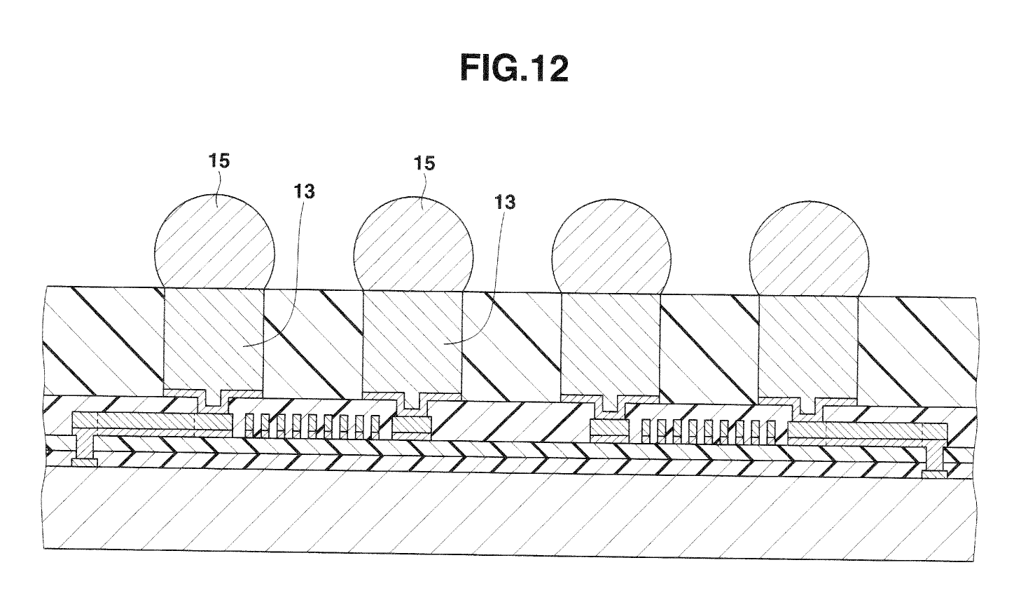

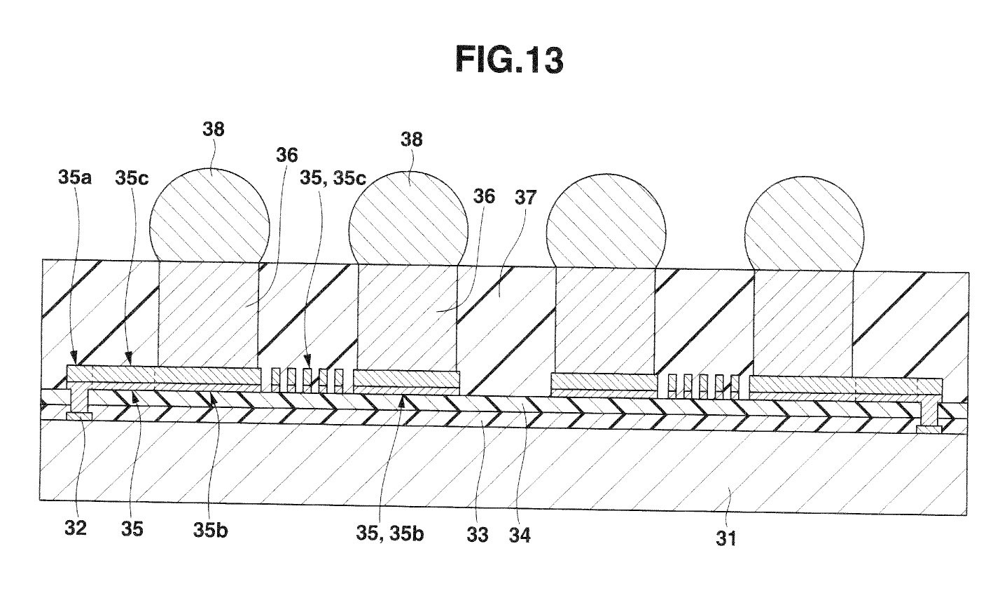

Then, the upper surface side of the sealing film 14 is properly ground to expose the upper surfaces of the columnar electrodes 13 as shown in FIG. 11, and the upper surface of the sealing film 14 including the upper surfaces of the exposed columnar electrodes 13 is planarized, as shown in FIG. 11. Further, as shown in FIG. 12, solder balls 15 are formed on the upper surfaces of the exposed columnar electrodes 13. After a dicing step, a plurality of semiconductor devices shown in FIG. 1 are obtained.

In the semiconductor device thus obtained, the first wiring lines 7 are arranged on the first insulating film b so that the connection pad portions 7b of the first wiring line 7 form the outer circle. The second wiring lines 7 are arranged to extend between the connection pad portions 7b of the first wiring lines 7 so that the connection pad portions 7b of the second wiring line 7 form one circle or two or more circles inside the outer circle. The second insulating film 10 having openings 11 in parts corresponding to the connection pad portions 7b of the first and second wiring lines 7 is provided on the first insulating film 5 as well as on the first and second wiring lines 7. The columnar electrodes 13 having a planar size greater than the planar size of the connection pad portions 7b of the first and second wiring lines 7 are provided on the upper surfaces of the connection pad portions 7b of the first and second wiring lines 7 exposed via the openings 11 in the second insulating film 10 and on the second insulating film 10 around the connection pad portions 7b. As a result, the planar size of the connection pad portions 7b of the first wiring line 7 arranged to form the outer circle is smaller than the planar size of the columnar electrode 13. This permits a greater distance between the connection pad portions 7b of the first wiring line 7, and therefore permits less limitations on the drawing of the second wiring line 7 extending between the connection pad portions 7b of the first wiring lines 7.

One example of the dimensions of this semiconductor device is described here. Even when the pitch of the columnar electrodes 13 is 500 μm and the diameter of the columnar electrode 13 is 250 μm, the diameter of the connection pad portion 7b of the wiring line 7 can be 10 to 100 μm, preferably, 30 to 50 μm regardless of the above-mentioned dimensions. The diameter of the opening 11 in the second protective film 10 is 5 to 50 μm, preferably, 10 to 20 μm smaller than the diameter of the connection pad portion 7b of the wiring line 7 to allow for a tolerance.

In the semiconductor device shown in FIG. 1, when both the line width of the drawn line 7c of the wiring line 7 and the distance between the wiring lines 7 are 20 μm at the minimum, the distance between the connection pad portions 7b of the wiring line 7 can be 400 μm and great if the pitch of the columnar electrodes 13 is 500 μm, the diameter of the columnar electrode 13 is 250 μm, and the diameter of the connection pad portion 7b of the wiring line 7 is 100 μm. Consequently, as many as nine drawn lines 7c of the wiring lines 7 can be disposed between the adjacent connection pad portions 7b of the wiring line 7.

Moreover, in this semiconductor device, the wiring line 7 is covered with the second protective film 10, so that the reliability in the moisture resistance of the wiring line 7 can be enhanced. A photosensitive organic material having good electric properties and physical properties can be used as the material of the second protective film 10, such as polyimide, polybenzoxazole, polycarbodiimide, benzocyclobutene, polyborazine, or an epoxy or acrylic material. The thickness of the second protective film 10 can be 5 to 30 μm, preferably 10 to 15 μm, depending on the thickness of the wiring line 7.

What is claimed is:

1. A semiconductor device comprising:
a semiconductor substrate having integrated circuits formed in one surface;
a plurality of connection pads respectively connected to the integrated circuits along at least one combination of opposite sides of the semiconductor substrate;
a first insulating film provided above the semiconductor substrate;
a plurality of first wiring lines which are provided on the first insulating film and which are arranged so that connection pad portions thereof form an outer circle;
second wiring lines which extend between the connection pad portions of the first wiring lines and which are arranged so that connection pad portions thereof form at least one circle inside the outer circle;
a second insulating film which is provided on the first insulating film as well as on the first and second wiring lines and which has openings in parts corresponding to the connection pad portions of the first and second wiring lines; and
columnar electrodes which are provided above the upper surfaces of the connection pad portions of the first and second wiring lines exposed via the openings in the second insulating film and above the second insulating film around these connection pad portions, the columnar electrodes having a planar size greater than the planar size of the connection pad portions of the first and second wiring lines.

2. The semiconductor device according to claim 1, wherein a foundation metal layer is provided between the columnar electrode and the connection pad portions of the first and second wiring lines.

3. The semiconductor device according to claim 2, wherein the foundation metal layer has the same planar size as the columnar electrode.

4. The semiconductor device according to claim 1, wherein part of the second wiring line extends inside the outer circle through a region immediately under the columnar electrode.

5. The semiconductor device according to claim 1, wherein a sealing film is provided on the second insulating film to cover the peripheries of the columnar electrodes.

6. The semiconductor device according to claim 5, wherein solder balls are provided on the columnar electrodes.

7. A semiconductor device manufacturing method comprising the steps of:
preparing a semiconductor substrate which has integrated circuits formed in one surface and which has a plurality of connection pads respectively connected to the integrated circuits along at least one combination of opposite sides of the semiconductor substrate;
forming, above the semiconductor substrate, a first insulating film having openings, the openings exposing at least parts of the connection pads;
forming a plurality of first wiring lines and a plurality of second wiring lines on the first insulating film formed on the semiconductor substrate, the plurality of first wiring lines respectively having connection pad portions, the plurality of second wiring lines respectively having connection pad portions;
forming a second insulating film on the first insulating film as well as on the first and second wiring lines, the second insulating film having openings in parts corresponding to the connection pad portions of the first and second wiring lines; and
forming columnar electrodes above the upper surfaces of the connection pad portions of the first and second wiring lines exposed via the openings in the second insulating film and above the second insulating film around these connection pad portions, the columnar electrodes having a planar size greater than the planar size of the connection pad portions of the first and second wiring lines,
wherein the step of forming the wiring lines includes arranging the first wiring lines so that the connection pad portions thereof form an outer circle, and arranging the second wiring lines to extend between the connection pad portions of the first wiring lines so that the connection pad portions thereof form at least one circle inside the outer circle.

8. The semiconductor device manufacturing method according to claim 7, wherein the step of forming the columnar electrodes includes forming a foundation metal layer on the entire second insulating film as well as on the connection pad portions of the first and second wiring lines exposed via the openings in the second insulating film, forming a plating resist film having openings to form the columnar electrodes on the foundation metal layer, and forming, by electrolytic plating, the columnar electrodes on the foundation metal layer within the openings in the plating resist film.

9. The semiconductor device manufacturing method according to claim 8, wherein the step of forming the columnar electrodes includes, after forming the columnar electrodes on the foundation metal layer, releasing the plating resist film and removing the foundation metal layer using the columnar electrodes as masks.

10. The semiconductor device manufacturing method according to claim 9, further comprising the step of forming a sealing film on the second insulating film to cover the peripheries of the columnar electrodes after removing the foundation metal layer using the columnar electrodes as masks in the step of forming the columnar electrodes.

11. The semiconductor device manufacturing method according to claim 10, further comprising the step of forming solder balls on the columnar electrodes after forming the sealing film on the second insulating film in the step of forming the sealing film.
